(19) United States
(12) Patent Application Publication
(10) Pub. No.: US 2024/0097292 A1
(43) Pub. Date: Mar. 21, 2024

(54) LOW-CURRENT VOLTAGE SOURCE WATCHDOG

(71) Applicant: International Business Machines Corporation, Armonk, NY (US)

(72) Inventors: Mark K. Hoffmeyer, Rochester, MN (US); Matthew Doyle, Chatfield, MN (US); Kyle Schoneck, Rochester, MN (US); Layne A. Berge, Rochester, MN (US); Matthew A. Walther, Rochester, MN (US); Thomas W. Liang, Rochester, MN (US); John R. Dangler, Rochester, MN (US); Jason J. Bjorgaard, Rochester, MN (US)

(21) Appl. No.: 17/932,794

(22) Filed: Sep. 16, 2022

(51) Int. Cl. H01M 50/583; H05K 1/11

(52) U.S. Cl. CPC H01M 50/583; H05K 1/111; H05K 2201/10037; H05K 2201/10181

(57) ABSTRACT

A voltage source watchdog comprising a passive device is placed in series between a voltage source and a load. The passive device includes an electromigration (EM) joint of known materials that will create an electromigration void after a specified amount of current passes through the EM joint. After a known amount of current as passed through, a void is created and a voltage will no longer be sensed, thus providing a sure safety mode situation. When the voltage source is a battery, the battery life may be extended by selectively enabling voltage measurement operations for the proposed watchdog.

### BACKGROUND

The present invention relates generally to the field of power management, and more particularly to monitoring power in voltage sources.

Cryptographic cards require security protection while under battery power supply according to the PCI (payment card industry) Data Security Standard.

MEMS (micro-electro-mechanical systems) and the related micromechatronics and microsystems make up the technology of microscopic devices, particularly those having moving parts. MEMs are miniature machines that have both mechanical and electronic components. MEMs can be embedded within silicon to perform certain mechanical tasks based on electrical input.

### SUMMARY

In one aspect of the present invention, an apparatus includes: (i) a component substrate having a wirebonding site configured for electrical connection between a voltage source and an electrical device; (ii) a wirebond including a wire having two terminal ends, the wire including a fused portion having a first length and two end portions, each end portion including one of the two terminal ends, the fused portion having a diameter smaller than the two end portions, the two terminal ends attached to the component substrate at the wirebonding site; and (iii) a first elecromigration (EM) joint at a first terminal end, the EM joint formed at a ball bond connecting the first terminal end of the wire to a metal pad at the wirebonding site.

In another aspect of the present invention, a circuit for a battery backup of a cryptographic card includes: (i) a cryptographic circuit board; (ii) a battery; (iii) a processor; and (iv) an electromigration (EM) joint assembly including a first wirebond having a first length of fused wire, the EM joint assembly electrically connected in series with the battery and the processor.

### BRIEF DESCRIPTION OF THE SEVERAL VIEWS OF THE DRAWINGS

FIG. 1 is a schematic view of a circuit according to the present invention;

FIG. 2 is a perspective view of a wirebond according to the present invention;

FIG. 3 is a perspective view of an electromigration timer according to the present invention;

FIG. 4 is a perspective view of as exemplary structure after a first layer of material is deposited on a substrate; and

FIG. 5 is a perspective view of an exemplary structure for a electromigration timer according to the present invention.

### DETAILED DESCRIPTION

Some embodiments of the present invention are directed to a voltage source watchdog comprising a passive device placed in series between the voltage source and load with an electromigration (EM) joint of known materials that will create an electromigration void after a specified amount of current passes through the EM joint. After a known amount of current as passed through, a void is created and a voltage will no longer be sensed, thus providing a sure safety mode situation. When the voltage source is a battery, the battery life may be extended by selectively enabling voltage measurement operations for the proposed watchdog. Applications for a battery watchdog including battery-backed processor memory.

Low-voltage applications often require prolonged battery life. For example, cryptographic cards require security protection while under battery power supply according to the PCI (payment card industry) Data Security Standard. The batteries used in these applications may drain prematurely if continuous monitoring is performed to ensure sufficient battery power is available. A low-current battery watchdog is presented herein for periodic assurance of battery power over a prolonged period of time, which may be, for example, from one and five years. Other areas in which the low-current voltage source watchdog may be applied include IoT (internet of things), automotive applications, and computing servers. IoT devices may be improved by monitoring low-power circuit health using the disclosed watchdog using EM joints to monitor voltage source power. Regarding automotive applications, any circuit with a fuse can be improved by use of the disclosed watchdog using EM joints to monitor voltage source power. The use of the EM joints eliminates the need for added circuitry to monitor for over-current conditions because the EM joints would create an open condition upon exposure to an over-current condition.

Pre-emptive measures are often taken when low battery power conditions arise such as shutting down a system or destroying saved data for security purposes. Sometimes the low-battery condition is a false-positive event. Managing battery life over the course of a five-year life is achieved by inserting into an existing circuit a low-current voltage source watchdog, also referred to herein as a battery watchdog, that periodically confirms battery power and operates to identify a failing battery before the system takes pre-emptive low-battery actions. The voltage source watchdog device utilizes EM-controlled, or EM-tuned, sensors.

By targeting the wirebond to pad interface failure, the failure may be designed into the circuit creating a predictable duration before failure. With that predictable duration established, one is able to know the voltage source is still functional because the voltage source is capable of generating the expected failure at the target time. Multiple electromigration-based sensors are set up to fail at various times establish periodic voltage checks upon failure or lack thereof. A voltage measurement circuit may continuously or periodically monitor voltage across the load or DUT.

Some embodiments of the present invention recognize the following facts, potential problems and/or potential areas for improvement with respect to the current state of the art: (i) cryptographic hardware is subject to battery function requirements of three to five years without service; (ii) if, at any point, the cryptographic hardware detects a low voltage on the battery domain, the hardware will automatically go into safe mode and destroy any saved data; (iii) conservation of battery life should be carefully considered to achieve a five-year battery life; (iv) with enough current flow, metals can move by electromigration, creating voids and/or shorts in micro-electro-mechanical systems (MEMs); (v) electromigration is dependent on current flow, material, cross sectional area, and metallurgy; (vi) precise design for electromigration supports a known time when a desired Kirkendall void will occur; (vii) some cryptographic hardware maintains current draw below 100 μA (˜30 to 60 μA); and (viii) monitoring battery life tends to drain the battery power.

In one aspect of the present invention, an apparatus includes: (i) a component substrate having a wirebonding site configured for electrical connection between a voltage source and an electrical device; (ii) a wirebond including a wire having two terminal ends, the wire including a fused portion having a first length and two end portions, each end portion including one of the two terminal ends, the fused portion having a diameter smaller than the two end portions, the two terminal ends attached to the component substrate at the wirebonding site; and (iii) a first elecromigration (EM) joint at a first terminal end, the EM joint formed at a ball bond connecting the first terminal end of the wire to a metal pad at the wirebonding site. The EM joint advantageously provides a sensor for battery status in that while the EM joint carries current, the battery is indicated as in good condition.

In another aspect of the present invention, the diameter of the fused portion is defined according to a specified current to pass through the wirebond. By setting the diameter to a specified current associated with the application, the EM joint of the wirebond can be designed to fail after a designated number of years of operation.

In yet another aspect of the present invention, the voltage source is a battery and the electrical device is a cryptographic card. Some embodiments of the present invention advantageously support battery backed memory of a cryptographic card.

In still yet another aspect of the present invention, the diameter and the first length of the fused portion are sized to carry a specified current for a specified number of years before an open circuit forms due to electromigration at the EM joint. In this way, the electromigration failure of the EM joint is designed in such that so long as the EM joint passes current the measured voltage will indicate the status of the battery with a failure before the specified number of years suggests strain on the battery and, thus, a potentially bad battery.

In still another aspect of the present invention, the specified current is below 100 μA. Some embodiments of the present invention are directed to relatively low current applications below 100 μA with some applications as low as 30 μA.

In one aspect of the present invention, a circuit for a battery backup of a cryptographic card includes: (i) a cryptographic circuit board; (ii) a battery; (iii) a processor; and (iv) an electromigration (EM) joint assembly including a first wirebond having a first length of fused wire, the EM joint assembly electrically connected in series with the battery and the processor. The EM joint assembly advantageously provides a sensor for battery status in that while the EM joint assembly carries current, the battery is indicated as in good condition.

In another aspect of the present invention, a circuit for a battery backup of a cryptographic card includes a voltage measuring circuit electrically connected in parallel with the processor to read the voltage across the processor. The voltage measuring circuit advantageously provides for monitoring battery power while verifying current flow through the EM joint assembly.

In yet another aspect of the present invention, an EM joint assembly of a circuit for a battery backup of a cryptographic card includes a second wirebond having a second length of fused wire, the first and second wirebonds electrically connected in parallel, the second length being longer than the first length. A pair or more of wirebonds in the EM joint assembly allow for intermediate verification of the proper function of the EM joint assembly while providing a more controlled assurance of continued proper battery function.

In still yet another aspect of the present invention, the first length of fused wire is a middle portion of a wire having two end portions, the first length of fused wire being between the two end portions, each end portion including one of the two terminal ends, the fused portion having a diameter smaller than the two end portions, the two terminal ends attached to a component substrate of the EM joint assembly. The EM joint advantageously provides a sensor for battery status in that while the EM joint carries current, the battery is indicated as in good condition.

In still another aspect of the present invention, an EM joint assembly of a circuit for a battery backup of a cryptographic card includes an EM joint located at a first terminal end, the EM joint formed at a ball bond connecting the first terminal end of the wire to a metal pad at a wirebonding site on the component substrate. The EM joint advantageously provides a sensor for battery status in that while the EM joint carries current, the battery is indicated as in good condition.

The Kirkendahl effect and Kikendahl voids are a result of thermally or electrically (electromigration) driven atomic diffusion. The Kirkendall effect is the motion of an interface between two metals that occurs as a consequence of the difference in diffusion rates of the metal atoms. If one atomic species diffuses faster across an interface from an element, phase, or compound relative to the diffusion rate of another element, phase, or compound, the resulting interface motion and buildup of a concentration of atomic vacancies at the interface leads to voids being formed. As diffusion proceeds, the atomic vacancies coalesce into microscopic voids at the interface. Significant buildup of voids at the interface may compromise the mechanical and electrical integrity of that interface, which leads to electrical failures. Kirendahl voids are observed occurring in various electronic interconnections including: (i) solder joints; (ii) wirebonds; and (iii) sintered-co-fired metals and/or ceramics.

Mean time to failure (MTTF) due to electromigration can be calculated by Black's

equation:

$$M T T F = \frac{A}{{j}^{n}} exp ( \frac{{E}_{a}}{k T} ) ,$$

where, A is a cross-sectional-area-dependent constant, j is the current density, n is a scaling factor (usually set to 2), Eₐ is the activation energy for electromigration, k is Boltzmann's constant, and T is the absolute temperature in Kelvin. Electrical failures caused by electromigration include: (i) deposition of atoms, hillocks, which result in a short; and (ii) depletion of atoms, voids, which result in an open.

Some embodiments of the present invention are directed toward identifying and/or monitoring the operational status of the battery backup of a cryptographic card over a period of years, often exceeding seven years. By reliably identifying the operation status of the battery backup, false battery function fails may be avoided, thus reducing unnecessary repair and/or replacement. Some embodiments of the present invention employ a series of EM fuses or EM/thermal fuses allowing for monitoring battery function at very low currents, typically below 100 uA.

According to some embodiments of the present invention, a passive device is placed in series between a voltage source and a load. The passive device is constructed and/or inserted to include an electromigration joint. The electromigration joint is made of materials known to create an electromigration void after a specified current density, j, flows through the joint for a pre-determined duration, T. Accordingly, in some embodiments of the present invention, upon being exposed to the specified current density for the specified amount of time, or duration, a void will be created and a voltage will no longer be sensed, thus providing a sure safety mode situation. Alternatively, at a designated duration, T, the circuit is evaluated to determine whether or not the passive device is in an open condition. It the open condition occurs at the specified duration, the voltage source power is confirmed to be at an operational level. If the open has not occurred, the voltage source power is flagged as being below the operational level. The voltage source power is suspect, or flagged, because the lack of an open condition suggests the passive device has been exposed to a lower current density than needed for an operational voltage source or battery cell. Should an evaluation disclose that the open condition occurred before the designed duration, T, then one may predict that the voltage source may fail earlier due to excessive current density flowing through the passive device.

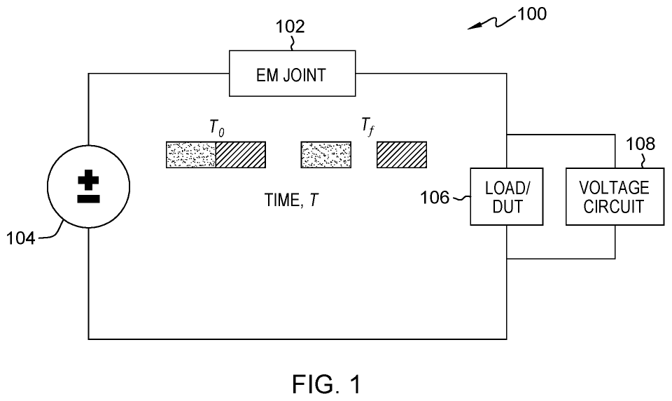

FIG. 1 is a circuit diagram showing a battery and a load having a electromigration (EM) joint in which the battery is monitored for operational status. Circuit 100 includes: voltage source 104; EM joint 102, load, or device under test (DUT), 106, and voltage measurement circuit 108. In this example, the EM joint includes a packaged battery watchdog. The EM joint is designed for electromigration to cause an open circuit at the EM joint at pre-defined time lapse, from Tₒ to T_{f}, where Tₒ is initial time and T_{f} is the time of failure, or open circuit. At the time of failure, the EM joint breaks the flow of current through the joint, causing an open circuit condition.

According to some embodiments of the present invention a voltage measurement is taken by voltage measurement circuit 108 across load/DUT 106 during normal operation to establish a baseline for the duration of the EM joint. Where voltage source 104 is a battery, the voltage may be monitored periodically, such as, for example, 1 Hz, 0.1 Hz, one per minute, or one per hour. If battery life is critical, the voltage measurement circuit is disabled except for when measurement operations are required. By disabling or limiting the frequency of voltage measurement, the battery life is longer than if continuous voltage measurements were taken. The load/DUT resistance may drop for a variety of reasons including: (i) during tampering of the cryptographic card; and (ii) during operations that are out of specification and potentially damaging to the circuit being powered.

Some embodiments of the present invention are directed to multiple electromigration (EM) sensors in a single system having various designed durations to EM failure. For example, a first electromigration sensor may be designed for a duration to EM failure of T₁ and a second electromigration sensor may be designed for a duration to EM failure of T₂, where T₂ is greater than T₁. When the two EM sensors are arranged in parallel circuit with a battery generating a known current, the first EM sensor will fail after a first duration, earlier than the second EM sensor. Intermediate determinations of battery condition are achieved with multiple electromigration (EM) sensors in a single system having various designed durations to EM failure.

Some embodiments of the present invention operate in applications with current demand in the range of 100 uA to 300 mA. Some embodiments of the present invention deployed by on-chip metallization function below 100uA. On-chip metallization may be implemented within a new semiconductor chip, an ASIC (application-specific integrated circuit), or as a stand-alone smaller chip that works as part of a regulator feedback loop. Further, with respect to wirebond embodiments of the present invention, adding a prestress burn consisting of a high continuous current or a high temp thermal age exposure, used independently or in tandem, drives a substantial amount of interfacial degradation on burned-in hardware such that relatively lower level currents and lower temperatures in operation can carry the electromigration joint to failure within specified functional time windows.

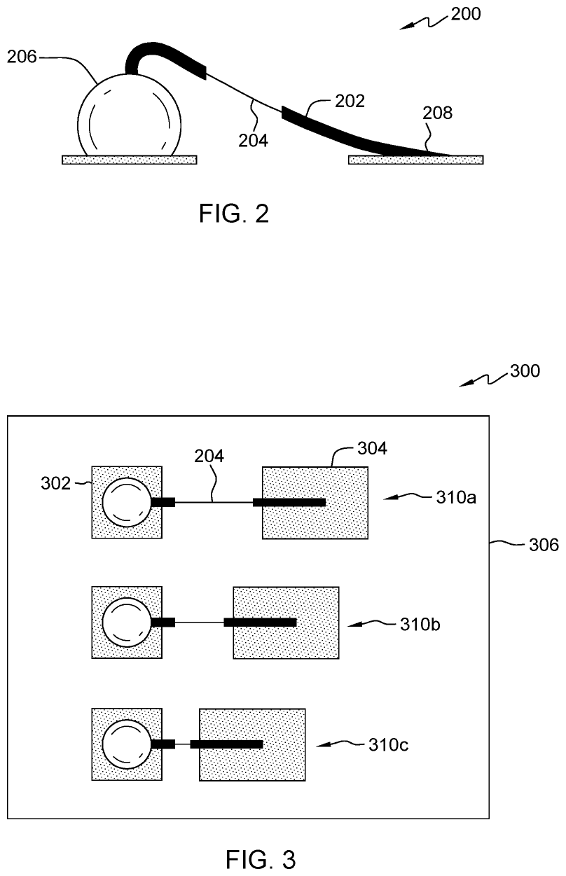

FIG. 2 is a wirebond according to embodiments of the present invention. Wirebond 200 includes: bond wire 202, Rayleigh filament 204, ball bond 206, and wedge bond 208. The bond wire of original diameter is processed to form the Rayleigh filament of a specified length and diameter for causing interface failures by electromigration. The interface failure may by designed to occur at the ball bond or the wedge bond. Diffusion occurs at the bonded weld.

Fused wirebonds can be prepared initially by a fusing process, then installed. Initial preparation may involve applying an external thermal treatment to the bond wire. The wirebond to pad interface may deteriorated after installation to drive eventual targeted electromigration failure. The fusing process may be applied to bond wires made of any noble metal such as gold, which forms a filament for purposes of the sensor.

According to some embodiments of the present invention, historic failures of certain wirebonds in the field provide the data needed to predictably create electromigration fuses for periodically confirming battery life.

According to some embodiments of the present invention, the timeframe, or duration in which a wirebond will be targeted to fail can be one month to six years.

Some embodiments of the present invention are directed to an independent electronic package consisting of one or more wirebonds attached to a substrate with wirebond connections terminating to peripheral leads or array pads is proposed as a sensor packaging solution.

One use case for the electronic package is a battery watchdog in a cryptographic card application. The electromigration fuse is made exceedingly small to drive significant joule heating into the interconnect of the fuse itself to ensure electromigration driven diffusion can proceed to failure when used in the application. The small size is achieved by creating a wirebond package in which wirebonds are made sufficiently small, such that their bond interfaces can be significantly heated with application of low current to create an electromigration fuse, or series of fuses.

FIG. 3 is a packaged set of wirebond sensors for installation into a circuit, such as circuit 100 (FIG. 1). Wirebond sensor package 300 includes: gold plated pads 302; wirebond jumper pads 304; component substrate 306; and a set of wirebond timers, or sensors, 310a, 310b, 310c.

The current carrying limits of wirebonds of a given material and wire diameter to their onset of fusing (melting) in air are generally approximated by the Preece equation:

$$i = k {D}^{\frac{3}{2}} ,$$

where i=max current (amps), D=wire diameter (in), and k is a material constant (for Au, k=10,244), Equation is valid for free standing wirebonds in AIR to wire lengths of <0.040″.

For wirebonds of varying length, the modified Preece Equation is used and highlighted in MIL Spec standards MIL-M-38510, and is based on a Joule heating model which reduces to a simplified form where the maximum current, I (amps), to fusing is proportional to the following expression:

$$l α \sqrt{\frac{k}{ρ}} \frac{{D}^{2}}{l} ,$$

where k=thermal conductivity of the wire material, p=electrical resistivity of the wire material, D=wire diameter and l=length of the wirebond.

According to some embodiments of the present invention, a post wirebond processing method involving the addition of a short burst of pulsed current is provided such that the individual bonded wires melt and/or fuse. This is one way that the wirebonds are made sufficiently small to operate as a cryptographic battery watchdog. The individual bond wires melt by the proposed method at their approximate centerline with molten metal pulling back by control of capillary action and surface tension to create very fine filaments.

The very fine filaments described herein are also referred to as Rayleigh filaments. The formation and ultimate stability of the filaments was studied and determined by Lord Rayleigh, where the maximum fused gap or filament length is equivalent to 4.51*d, where d is the starting diameter of the wire. The specific amount of current and time duration of pulsed application of current can be tuned to specific bond wires and wirebond lengths to create fused filaments of varying length on wirebonds of varying length with filaments of length up to the Rayleigh instability limit of 4.51*d. By making a wirebond package with Rayleigh filaments, very high working temperatures of wirebonds can be achieved with very low current levels.

Using a package of sensors with bond wires having fused sections of varying length will allow regulation for durations of time, T, when battery operation is confirmed. The ability to create sensors that will fail over varying durations can be used in a variety of watchdog applications including for cryptographic cards. Having multiple wirebonds in parallel creates current sharing and allows for proper battery function detection over time as the presence of wirebonds of different lengths with Raleigh filaments of different lengths will fail at different times over the life of the product. According to some embodiments of the present invention, when one wire in parallel fails, the remaining wire(s) share more current, but those wire(s) are also designed to be capable of carrying more current as well as part of the “timer circuit.” For example, any remaining wirebonds may be made with relatively shorter length wires and/or with larger diameter filaments. In that way, the longest wire/filament has the shortest time to fail. When a wire fails, voltage and/or resistance changes are be detected. This process continues as parallel wires in the circuit fail over lengthier periods of time.

For example, using a 0.8 mil diameter starting bond wire (20 μA), a Raleigh filament of approximately 0.08 mil (2 μA) can be created via a fusing process. The maximum current, per the Preece Equation, that can be carried in a 0.08 mil wire is 7.3 mA. Maximum current using the modified Preece Equation for a Rayleigh filament length of 125 micron with the properties of gold material at a temperature of 400 C is approximately 3.1 mA.

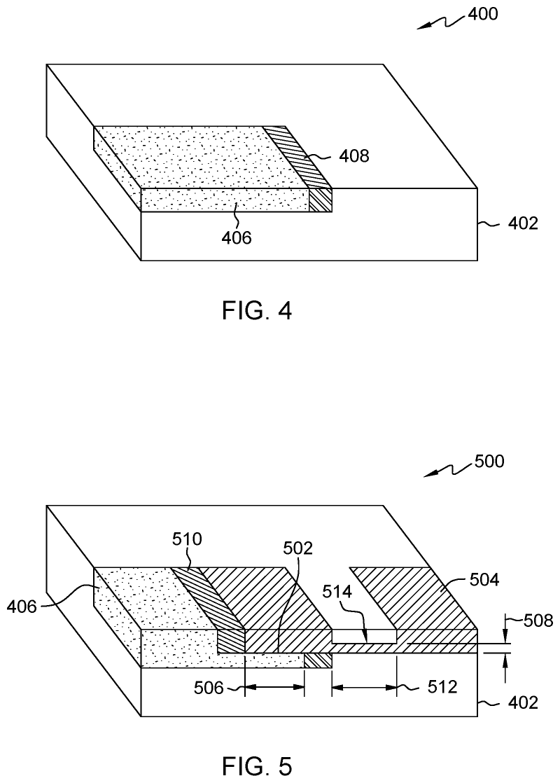

According to another embodiment of the present invention, chip metallization establishes the electromigration joint via lithography of a semiconductor structure. As described with respect to FIGS. 4 and 5, lithographic techniques are used to create an electromigration joint having specific characteristics designed for electromigration failure upon exposure to a specified current density of a defined period of time.

Referring now to FIGS. 4 and 5, an exemplary structure for forming an electromigration timer, or sensor, device includes a semiconductor substrate 402. Trenches are formed in the semiconductor substrate 402 with a thickness less than that of the substrate. Material layers 406 and 408 are deposited on the surface of the trench using thin film methods known in the art to form partial structure 400 of FIG. 4. Material layer 406 may be one of the following metals: Cu, Al, Chrome, Ag, Au, and Ni. Material layer 408 is a dielectric material for electrical isolation of a material layer 406.

Electromigration (EM) timer 500 is formed by depositing a layer of substrate 402 and forming a trench through the deposited layer to the top surface of structure 400. A second layer of materials are deposited over material layers 406 and 408, the second layer including metal layer 504. The second layer is placed such that metal layers 504 and 406 overlap distance 506 creating electromigration interface 502. Metal layers 504 and 406 are made of different metals including Cu, Al, Chrome, Ag, Au, and Ni. Material layer 408 is a dielectric material to electrically isolate metal layers 504 and 406. Dielectric 510 of the second layer of materials electrically isolates the metal layers 504 and 406 with the exception of the electrical connectivity at electromigration interface 502.

The electromigration interface 502 may be programmed for particular duration prior to loosing electrical connectivity by electromigration-induced voids. Dimensions 508 and 512 are tunable characteristics of thin current carrying member 514, which limits current flow to a specified amount. When current flow exceeds the specified amount of current the EM interface 502 may develop EM-induced voids earlier than the designated duration. Alternatively, when current flow exceeds the specified amount of current, the thin member 514 fails, causing an open condition across the thin member. The dimension 506 is a tunable characteristic of the EM interface. The surface area of the EM interface in conjunction with the current flow limitations establish time to failure targets for loosing electrical connectivity by electromigration-induced voids. FIG. 5 illustrates a single EM timer. Multiple EM timers having varying time to failure designs permit periodic battery integrity checks based on actual time to failure for each EM timer.

Electromigration interfaces may be based on the following metal layer EM pairs (404/406 pairs): Cu to Al, Al to chrome, Cu to Chrome, Cu to Ag, Cu to Au, and Al to Au. Other EM paired metals may be used in accordance with embodiments of the present invention.

According to some embodiments of the present invention, the construction and process flow for creating a watchdog sensor package with electromigration (EM) fuses includes: (i) building a watchdog component substrate; (ii) create a wirebond assembly; (iii) run high current pretreat on wirebond assembly to create Rayleigh filaments on the individual bond wires; (iv) apply a protective cover on the assembly; and (v) assemble the wire into the target circuit, such as on a cryptographic board for a security card.

The watchdog component substrate 306 may be created from, but not limited to, the following: (i) circuit board laminate, (ii) ceramic, and (iii) leadframe (FIG. 3). For example, component substrate 306 includes gold plated pads 302 suitable for wirebonding a device with aluminum pads mounted on it or aluminum slugs that can be mounted on the substrate. The component substrate may by make with wirebond jumper pads 304, plated with nickel and hard or doped gold. The component substrate may include a single wirebonding site, 310a to create a single electromigration-timed connection. The component substrate may include multiple wirebonding sites, 310a, 310b. 310c, for serial connections or for parallel connections to create multiple timed watchdogs. The wirebonding sites may be within the component substrate or wired into the substrate at the application assembly level.

The wirebond assembly may be created by thermosonic assembly or by ultrasonic assembly or other assembly technique now know or to be known in the future. The individual bond wires may be made of materials including, but not limited to: (i) aluminum; (ii) copper; (iii) gold; (iv) silver; and (v) palladium.

Pretreating the wirebonds of the assembly with high heat may be achieved by varying current/pulse to create filaments of a desired length up to the Rayleigh instability limit of the material, 4.51*d.

Assembly of the packaged watchdog component into a target circuit may be achieved using several techniques, including, but not limited to: (i) soldering; and (ii) a separable connector. The assembly may be a peripheral lead or array package for SMT soldering or connector socketing. The assembly may consist of single or multiple wirebond wires, where the presence of parallel circuitry to wirebonds may offer additional options for monitoring electromigration failures over time, especially when the assembly package is made with wirebonds of varying length, or of different bond wire materials and/or diameters.

Some embodiments of the present invention may include one, or more, of the following features, characteristics and/or advantages: (i) safety mode situations are detected by physical evidence of a void forming at a strategically defined electromigration joint; and (ii) monitoring for periodic failures according to EM timers reduces drain on batteries that would be found in continuous monitoring of the battery itself.

A wide variety of tuning parameters are available to the skilled technician. This wide variety of tuning parameters allows for a sequence of time to fail through the duration of product life when using multiple individual watchdog packages with single wirebonds or when using a watchdog package that has multiple wirebonds that can be wired to the application in parallel.

Time to fail durations of thermal diffusion/electromigration fuse packages made with wirebonds can be adjusted by varying multiple construction and/or watchdog process parameters, including: (i) wirebond or chip/thin film wire length; (ii) substrate pad metallurgy for wirebonds or chip metallization (Al, Au, and Ag); (iii) pad plating dopant additions (for example, make wirebond or chip pads with hard gold plating containing palladium, iron, silver, platinum, and silicon; (iv) pad metallurgy thickness; (v) wirebond or chip wire material such as Au, Pd, Ag, Pt, Cu, Al; (vi) starting wire diameter or chip trace width; (vii) fusing current and time pulse (wirebond only); (viii) thermal pretreatment post wirebonding or chip trace (burn in); and (ix) electrical pretreatment post wirebonding or chip trace (burn in).

Some helpful definitions follow:

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein that are believed as maybe being new, this understanding, as indicated by use of the term “present invention,” is tentative and provisional and subject to change over the course of patent prosecution as relevant information is developed and as the claims are potentially amended.

Embodiment: see definition of “present invention” above — similar cautions apply to the term “embodiment.”

and/or: inclusive or; for example, A, B “and/or” C means that at least one of A or B or C is true and applicable.

What is claimed is:

1. An apparatus comprising:
a component substrate having a wirebonding site configured for electrical connection between a voltage source and an electrical device;
a wirebond including a wire having two terminal ends, the wire including a fused portion having a first length and two end portions, each end portion including one of the two terminal ends, the fused portion having a diameter smaller than the two end portions, the two terminal ends attached to the component substrate at the wirebonding site; and
a first elecromigration (EM) joint at a first terminal end, the EM joint formed at a ball bond connecting the first terminal end of the wire to a metal pad at the wirebonding site.

2. The apparatus of claim 1, wherein the diameter of the fused portion is defined according to a specified current to pass through the wirebond.

3. The apparatus of claim 1, wherein:
the voltage source is a battery.

4. The apparatus of claim 1, wherein the electrical device is a cryptographic card.

5. The apparatus of claim 1, wherein the diameter and the first length of the fused portion are sized to carry a specified current for a specified number of years before an open circuit forms due to electromigration at the EM joint.

6. The apparatus of claim 5, wherein the specified current is below 100 i.tA.

7. A circuit for a battery backup of a cryptographic card comprising:
a cryptographic circuit board;
a battery;
a processor; and
an electromigration (EM) joint assembly including a first wirebond having a first length of fused wire, the EM joint assembly electrically connected in series with the battery and the processor.

8. The circuit of claim 7, further comprising:
a voltage measuring circuit electrically connected in parallel with the processor to read the voltage across the processor.

9. The circuit of claim 8, wherein:
the voltage measuring circuit is normally open and voltage is measured when the circuit is closed, thereby permitting periodic voltage measurements.

10. The circuit of claim 7, wherein the EM joint assembly further includes:
a second wirebond having a second length of fused wire, the first and second wirebonds electrically connected in parallel, the second length being longer than the first length.

11. The circuit of claim 7, wherein:
the first length of fused wire is a middle portion of a wire having two end portions, the first length of fused wire being between the two end portions, each end portion including one of the two terminal ends, the fused portion having a diameter smaller than the two end portions, the two terminal ends attached to a component substrate of the EM joint assembly.

12. The circuit of claim 11, wherein the EM joint assembly further includes:
an EM joint located at a first terminal end, the EM joint formed at a ball bond connecting the first terminal end of the wire to a metal pad at a wirebonding site on the component substrate.

13. A semiconductor structure for an electromigration timer, the semiconductor structure comprising:
a semiconductor substrate; and
an electromigration (EM) timer embedded in the semiconductor structure and comprising a first contact and a second contact, the first contact having tunable characteristics for defining a duration of electrical connectivity, the duration of electrical connectivity ending upon formation of an EM-induced void at an EM interface creating an open circuit condition;
wherein:
the first contact in electrical communication with the second contact at the EM interface where the first electrical contact overlaps the second electrical contact; and
the tunable characteristics of the first contact include a surface area of the EM interface and a thin current carrying member limiting current flow through the EM interface by a specified amount.

14. The semiconductor structure of claim 13, wherein the tunable characteristics at the electromigration interface include contact width, overlap length, and contact thickness for each of the first and second contacts and contact width and thickness of the thin current carrying member of the first contact.

15. The semiconductor structure of claim 13, further comprising:
a dielectric material isolating portions of the first contact from portions of the second contact to define an overlap length at the electromigration interface.

16. The semiconductor structure of claim 13, wherein the first and second contacts are composed metals making up an electromigration pair of dissimilar metals.

17. The semiconductor structure of claim 16 wherein the first contact is copper (Cu) and the second contact is aluminum (Al).
